(19) United States
(12) Patent Application Publication
(10) Pub. No.: US 2013/0069685 A1
(43) Pub. Date: Mar. 21, 2013

(54) INTEGRATED CIRCUIT TEST SOCKET HAVING TEST PROBE INSERTS

(71) Applicant: Mark A. SWART, Villa Park, CA (US)

(72) Inventor: Mark A. SWART, Villa Park, CA (US)

(21) Appl. No.: 13/618,871

(22) Filed: Sep. 14, 2012

Related U.S. Application Data
(60) Provisional application No. 61/535,789, filed on Sep. 16, 2011.

(51) Int. Cl. G01R 31/26

(52) U.S. Cl. 324/756.02

(57) ABSTRACT

A test socket having a lid and a base with a cavity for receipt of an integrated circuit and removable test probe inserts having test probes positioned around a perimeter of the cavity.

### CROSS-REFERENCE TO RELATED APPLICATION(S)

This Application claims priority to U.S. Provisional Application No, 61/535,789 filed Sep. 16, 2011, the contents of which are incorporated herein by reference.

### BACKGROUND OF THE INVENTION

The present invention pertains generally to devices that test integrated circuits, and more particularly to an improved test socket which is capable of making, on a repetitive basis, reliable connections between the integrated circuit leads and the test probes by incorporating customizable test probe inserts.

Integrated circuits are embodied within a chip, and are frequently encapsulated in rectangular ceramic or plastic packages that have contact pads or leads, which pads or leads are electrically connected to the integrated circuit. To test the integrated circuit it is necessary to make temporary electrical connections to the contact pads or leads on the integrated circuit package. Test sockets which may be soldered to printed circuit boards having the appropriate circuitry for testing a particular integrated circuit are commonly used for this purpose.

Traditional test socket designs include a lid which is either hinged to the test socket base along one edge or clipped to the test socket base along several edges, either of which is intended to clamp the integrated circuit down onto the contact pins of the test socket as the lid is closed. Typically, a test socket is designed to be able to test a specific chip or integrated circuit and separate test sockets are necessary for different integrated circuits or chips. Because most integrated circuits or chips require high precision in testing the corresponding test socket requires high precision, high cost manufacturing processes. Similarly because integrated circuits are tested in large volumes, test sockets can wear out and require replacement. Consequently a need exists for a test socket design for testing integrated circuits which can be manufactured with high precision with lower cost manufacturing processes and which can be easily modified to serve multiple applications.

### SUMMARY OF THE INVENTION

The present invention is directed to an integrated circuit test socket having removable test probe inserts which have an optimized test probe cavity designed to enhance the pointing accuracy of the test probes and provides a flexible design for easy modification to a desired length to serve multiple applications for a single test socket. The test probe inserts reduce the need for high precision, high cost manufacturing processes for a test socket and dramatically reduce test socket fabrication lead times. The test probe inserts are a two piece high precision molded insert that can be quickly cut down to fit a particular application and can be replaced if they are damaged or worn without reinvesting in a new test socket. Typically four inserts are utilized within a test socket around the perimeter of the cavity in which the integrated circuit is positioned for testing. Each insert includes a plurality of holes along one edge for positioning upon guide pins in the socket and a plurality of test probe cavities along the opposite edge of the insert which would contain the test probes. The length and width of each insert can be adjusted for each particular application depending upon the integrated circuit being tested. Each of the two pieces of the insert include a ledge to capture a chip alignment button for further positioning of the integrated circuit for testing.

These and other features of the present invention will be more fully disclosed in the following drawings and detailed description.

### BRIEF DESCRIPTION OF THE DRAWINGS

FIG. 1a is a top view of the lid and the base of the socket of the present invention;

FIG. 1b is a top view of the socket of FIG. 1a in an assembled condition;

FIG. 2a is a perspective view of the probe insert for the socket of the present invention;

FIG. 2b is a top view of the insert of FIG. 2a;

FIG. 3 is a top view of the base of the socket having a chip positioned therein; and

FIG. 3a is an enlarged detail view of FIG. 3.

### DETAILED DESCRIPTION

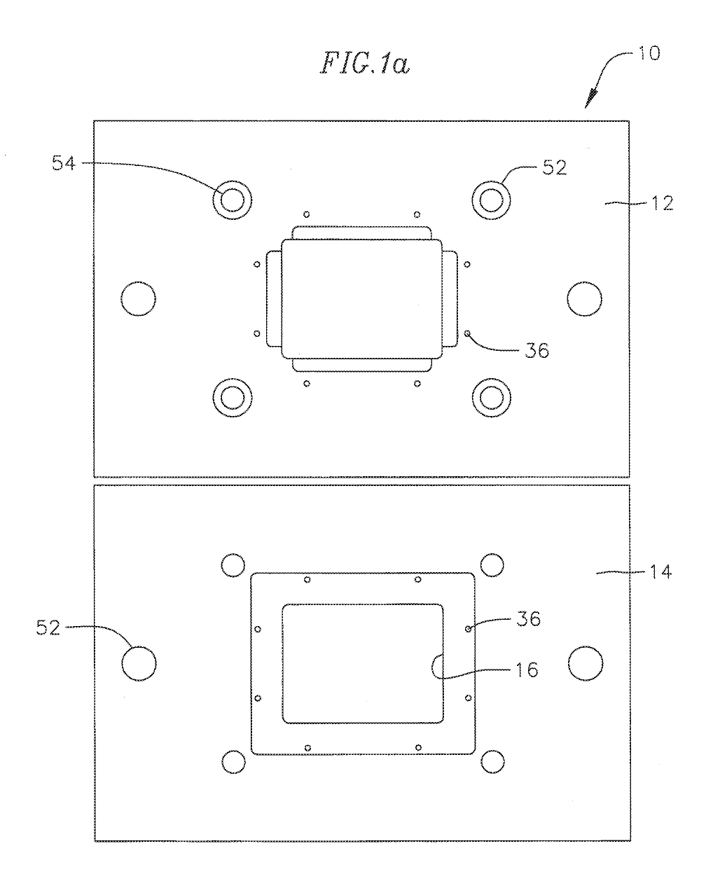

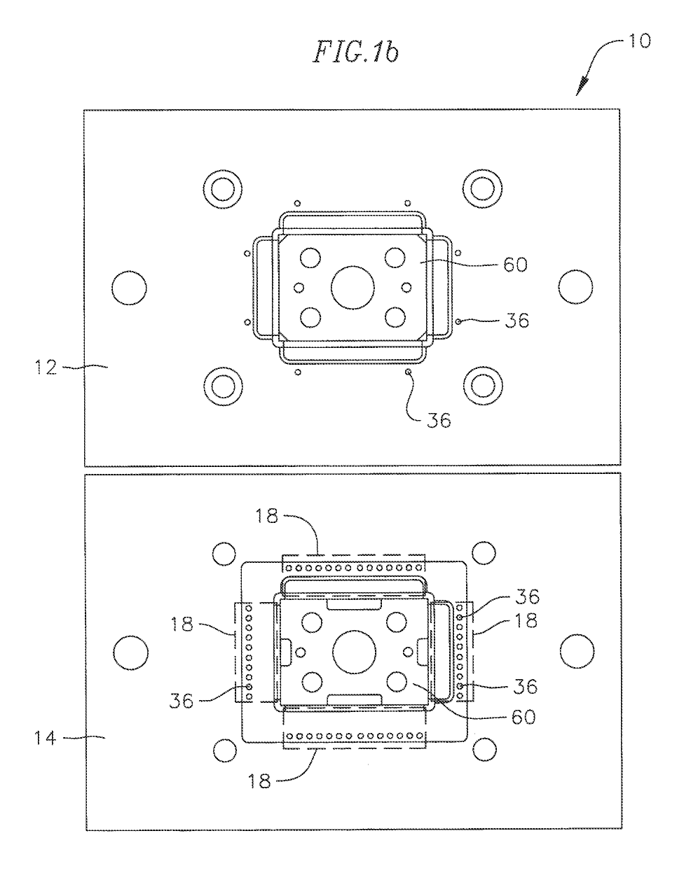

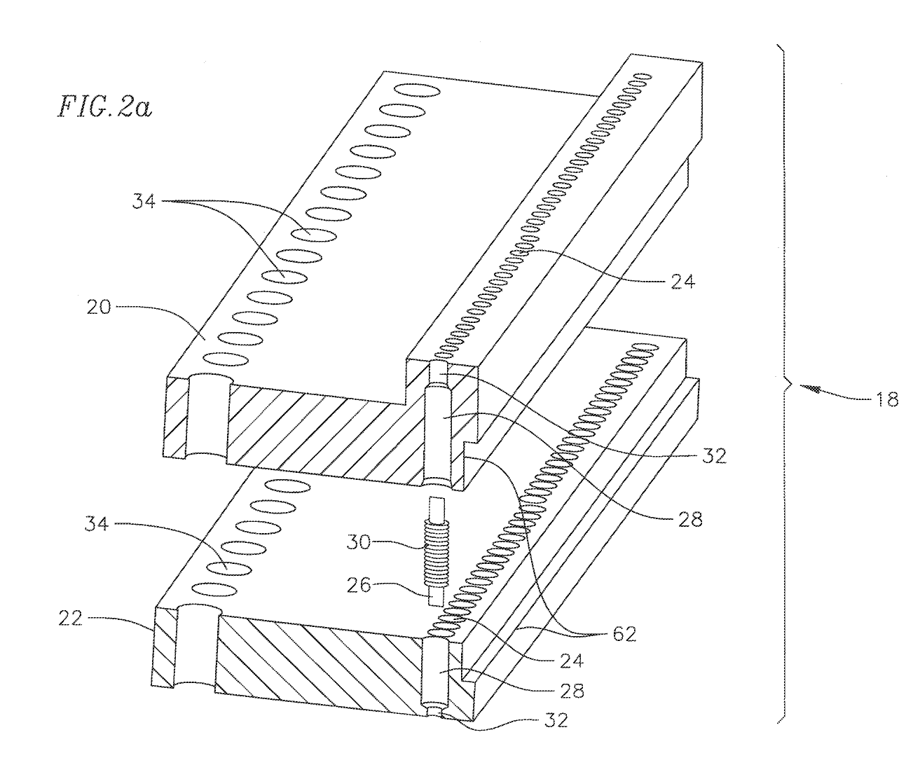

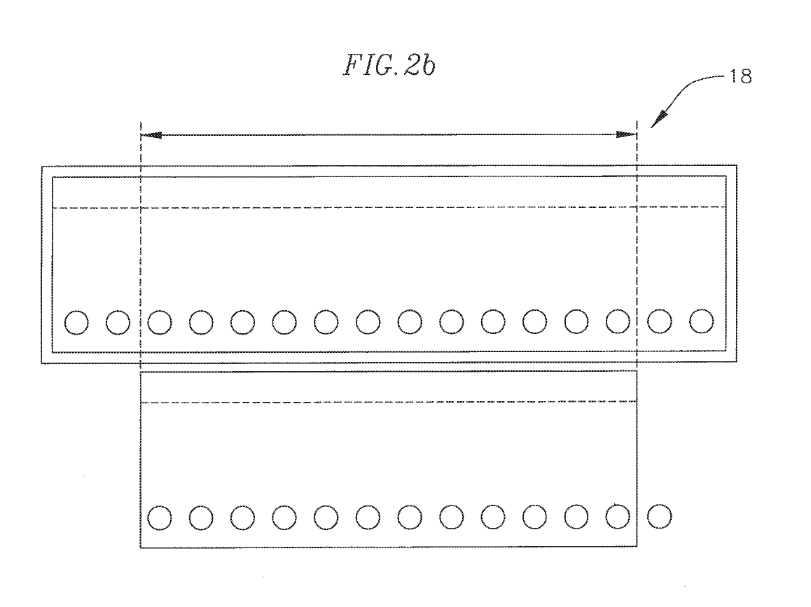

The present invention is directed to an integrated circuit test socket 10 as shown in FIGS. 1a and 1b. The socket includes a lid 12 and a base 14 upon which the lid is positioned. The base 14 has a cavity in which the integrated circuit positioned within a chip is positioned for testing. Positioned along the edges of the cavity are test probe inserts 18 as also shown in FIGS. 2a and 2b. Each insert 18 is a two piece high precision molded construction 20 and 22. Each insert includes a plurality of test probe cavities 24 for the positioning of a test probe 26 as required for each particular integrated circuit being tested. Each test probe cavity 24 has a larger diameter section 28 to accommodate a spring 30 of the test probe and a smaller diameter section 32 for either contact end of the spring probe to exit out of the insert. Insert sections 20 and 22 are positioned directly adjacent and on top of one another to create a unitary insert. The insert is typically a molded non-conductive plastic and is made of two individual pieces for the placement of the test probes within the insert. A row of positioning holes 34 is located through the insert opposite the test probe cavities which are used to position the inserts on guide pins 36 positioned around the cavity of the base. Guide pins 36 are also positioned in the lid to further align the inserts in the socket. As shown in FIG. 2b the two piece high precision molded insert can be quickly cut down to the desired size to fit the specific application.

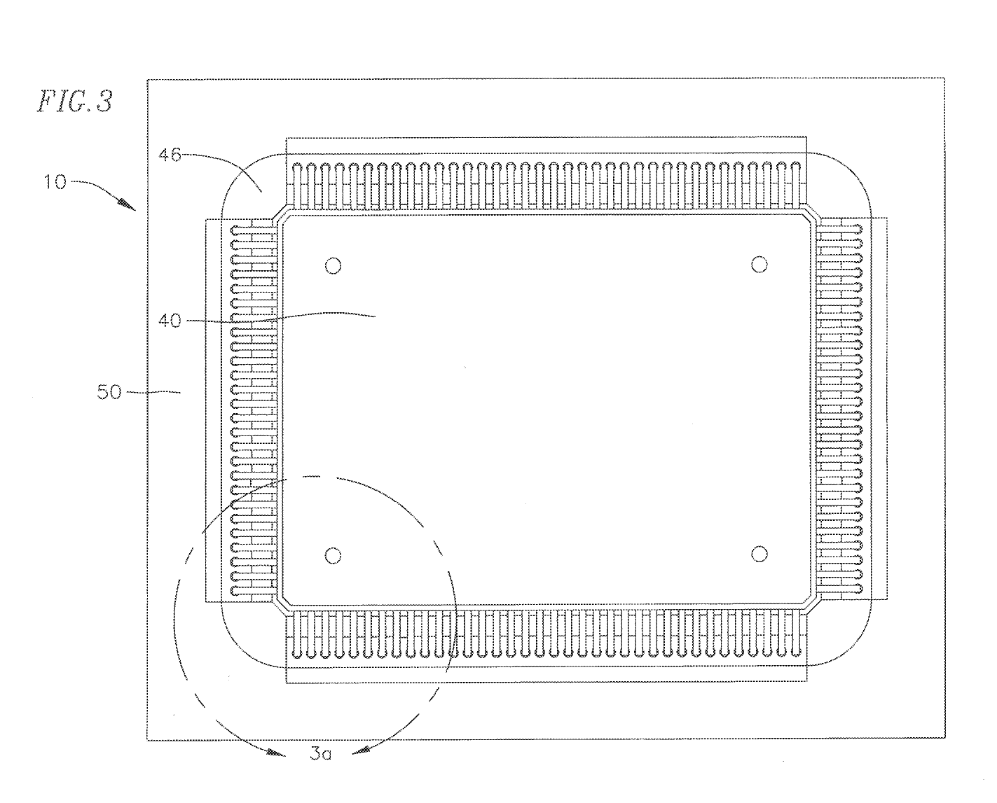

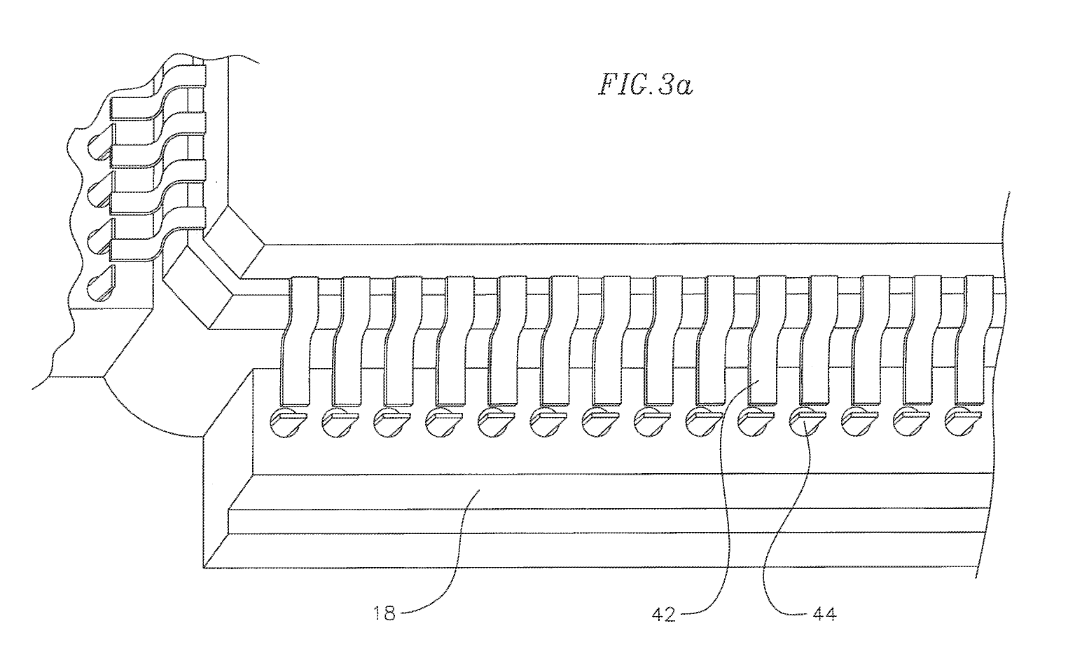

As seen best in FIG. 3 an integrated circuit, referred to herein as a chip 40 to be tested is positioned within the cavity 16 so that the peripheral leads 42 (FIG. 3a) are positioned over the insert 18 such that they engage the contact tip 44 of the test probes 26. Positioning of the chip 40 within the cavity is further insured by corner blocks 46 located at each corner of the chip. The socket 10 is positioned on a printed circuit board 50 having test pad locations for contacting the opposite contact tip of the test probes for transmission of the test signals from the integrated circuit to test electronics. The lid 12 and the base 14 also have holes 52 for receipt of guidepost 54 on the printed circuit board 50.

As shown in FIG. 1b an optional chip alignment button 60 can be positioned within either the lid or the base for further precision alignment of the chip within the cavity. As shown in

FIG. 2a, each portion 20, 22 of the insert 18 has a ledge 62 to capture the chip alignment button 60.

The socket of the present invention provides the advantages of having a two piece high precision molded test probe insert which can be quickly cut down to fit the particular application. The inserts have optimized cavity design to enhance the accuracy and performance of the test probes and the inserts can be replaced if they are damaged or worn without reinvesting in a new socket. The socket design reduces the need for high precision, high cost manufacturing processes and is a flexible design which allows easy modification of the inserts to a desired length to serve multiple applications. The socket can be reconfigured quickly which reduces the socket fabrication lead times.

Although the present invention has been described and illustrated with respect to a particular embodiment thereof, it is to be understood that the invention is not to be so limited since changes and modifications can be made therein which are within the fuller intended scope of the invention as hereinafter claimed.

What is claimed is:

1. A test socket comprising:
a lid;
a base having a cavity for receipt of an integrated circuit; and
at least one removable test probe insert having a plurality of test probes positioned around a perimeter of the cavity.

2. The socket of claim 1 wherein the test probe insert has a first component and a second component.

3. The socket of claim 1 wherein the test probe insert has a plurality of cavities for receipt of the test probes.

4. The socket of claim 1 wherein the test probe insert has a plurality of guide pin channels for positioning the insert on the socket.

5. The socket of claim 1 wherein the socket further has a plurality of positioning blocks for positioning the integrated circuit within the cavity.

6. The socket of claim 2 further comprising an alignment button within the cavity for alignment of the integrated circuit.

7. The socket of claim 6 wherein the first component and the second component have a ledge for receipt of the alignment button.

8. A removable test probe insert for an integrated circuit test socket comprising a first section and an adjacent second section each having a plurality of test probe cavities for receipt of a test probe and at least two guide pin channels for positioning the insert within the test socket.

9. The insert of claim 8 wherein the first component and the second component have a ledge for receipt of an alignment button.

10. The insert of claim 8 wherein the test probe cavities have a first diameter section and a reduced diameter section adjacent an outer surface.
